(19) United States
(12) Patent Application Publication
(10) Pub. No.: US 2024/0341197 A1
(43) Pub. Date: Oct. 10, 2024

(54) PIEZOELECTRIC SENSOR AND ELECTRONIC DEVICE

(71) Applicant: AAC Acoustic Technologies (Shanghai) Co., Ltd., Shanghai (CN)

(72) Inventors: Chengxiang Shu, Shanghai (CN); Wenbiao Xu, Shanghai (CN); Li Rong, Shanghai (CN)

(21) Appl. No.: 18/533,098

(22) Filed: Dec. 7, 2023

Related U.S. Application Data
(63) Continuation of application No. PCT/CN2023/087349, filed on Apr. 10, 2023.

(51) Int. Cl. H10N 30/88; H10N 30/30

(52) U.S. Cl. CPC H10N 30/883; H10N 30/302; H10N 30/853

(57) ABSTRACT

The present invention provides a piezoelectric sensor and an electronic device including the piezoelectric sensor. The piezoelectric sensor includes a piezoelectric ceramic layer having a first surface and a second surface, a first metal shrapnel mounted on the first surface, and a second metal shrapnel mounted on the second surface. A first cavity is formed between the first metal shrapnel and the piezoelectric ceramic layer and a second cavity is formed between the second metal shrapnel and the piezoelectric ceramic layer. The piezoelectric sensor further includes a first damping member located in the first cavity and a second damping member located in the second cavity. The second damping member is arranged symmetrically with the first damping member. The piezoelectric sensor and electronic device of the present invention can reduce the internal stress of the piezoelectric ceramic layer, thereby improving the reliability of the piezoelectric sensor.

### FIELD OF THE PRESENT INVENTION

The present invention relates to the field of sensor, and more particularly, to a piezoelectric sensor and an electronic device including the same.

### DESCRIPTION OF RELATED ART

Currently, the piezoelectric ceramic transducers are used in the buttons and other components of electronic products such as mobile phones and watches on the market, to achieve the functions of sensing and vibration. And it has achieved good user experience and market response. In related art, the piezoelectric ceramic transducers mainly have an arch shape or cymbal structures. However, due to the highly brittle and poor impact resistance of the piezoelectric ceramics, the piezoelectric ceramics are easy to be broken during the dropping reliability tests. This greatly limits the application and promotion of the piezoelectric ceramic transducers. At the same time, during use, when pressing the piezoelectric ceramic transducers, because it is easy to use excessive force, the arch-shaped or cymbal-shaped sensors will be deformed excessively, which may easily cause damage to the device.

Therefore, it is desired to provide a new piezoelectric sensor and a new electronic device which can overcome the above problems.

### SUMMARY

In view of the above, the embodiment of the present invention provides a new piezoelectric sensor. By the present invention, the piezoelectric sensor has high reliability.

The present invention provides a piezoelectric sensor including a piezoelectric ceramic layer. The piezoelectric ceramic layer includes a first surface and a second surface opposite to the first surface. The piezoelectric sensor further includes a first metal shrapnel mounted on the first surface and a second metal shrapnel mounted on the second surface. A first cavity is formed between the first metal shrapnel and the piezoelectric ceramic layer and a second cavity is formed between the second metal shrapnel and the piezoelectric ceramic layer. The piezoelectric sensor further includes a first damping member located in the first cavity and fixed on the first surface and a second damping member located in the second cavity and fixed on the second surface. The second damping member is arranged symmetrically with the first damping member.

As an improvement, one side of the first damping member is secured to the first surface of the piezoelectric ceramic layer, and the other side of the first damping member is abutted against the first metal shrapnel; one side of the second damping member is secured to the second surface of the piezoelectric ceramic layer, and the other side of the second damping member is abutted against the second metal shrapnel.

As an improvement, each of the first damping member and the second damping member is selected from one or more of foam, thermosetting glue, rubber, and silicone.

As an improvement, a length of the first damping member accounts for 10% to 90% of a length of the piezoelectric ceramic layer, and a length of the second damping member accounts for 10% to 90% of the length of the piezoelectric ceramic layer.

As an improvement, each of the first metal shrapnel and the second metal shrapnel includes a fixation portion fixed with the piezoelectric ceramic layer, an extension portion extending obliquely from the fixation portion in a direction away from the piezoelectric ceramic layer, and a horizontal portion extending horizontally from the extension portion.

In view of the above, the embodiment of the present invention provides a new electronic device. By the present invention, the piezoelectric sensor of the electronic device has high reliability.

The present invention provides an electronic device including a housing, a frame received in the housing, a button fixed to the housing, and a piezoelectric sensor located between the frame and the button. The piezoelectric sensor s a piezoelectric ceramic layer. The piezoelectric ceramic layer includes a first surface and a second surface opposite to the first surface. The piezoelectric sensor further includes a first metal shrapnel mounted on the first surface and a second metal shrapnel mounted on the second surface. A first cavity is formed between the first metal shrapnel and the piezoelectric ceramic layer and a second cavity is formed between the second metal shrapnel and the piezoelectric ceramic layer. The piezoelectric sensor further includes a first damping member located in the first cavity and fixed on the first surface and a second damping member located in the second cavity and fixed on the second surface. The second damping member is arranged symmetrically with the first damping member.

As an improvement, the electronic device further includes a supporting member connecting the piezoelectric sensor to the frame and a connecting member connecting the piezoelectric sensor and the button.

As an improvement, one side of the first damping member is secured to the first surface of the piezoelectric ceramic layer, and the other side of the first damping member is abutted against the first metal shrapnel; one side of the second damping member is secured to the second surface of the piezoelectric ceramic layer, and the other side of the second damping member is abutted against the second metal shrapnel.

As an improvement, each of the first damping member and the second damping member is selected from one or more of foam, thermosetting glue, rubber, and silicone.

As an improvement, a length of the first damping member accounts for 10% to 90% of a length of the piezoelectric ceramic layer, and a length of the second damping member accounts for 10% to 90% of the length of the piezoelectric ceramic layer.

As an improvement, each of the first metal shrapnel and the second metal shrapnel includes a fixation portion fixed with the piezoelectric ceramic layer, an extension portion extending obliquely from the fixation portion in a direction away from the piezoelectric ceramic layer, and a horizontal portion extending horizontally from the extension portion.

As an improvement, the fixation portion of the first metal shrapnel and the fixation portion of the second metal shrapnel are fixed with the piezoelectric ceramic layer by glue.

### BRIEF DESCRIPTION OF THE DRAWINGS

Many aspects of the exemplary embodiment can be better understood with reference to the following drawing. The components in the drawing are not necessarily drawn to scale, the emphasis instead being placed upon clearly illustrating the principles of the present invention. Moreover, in the drawings, like reference numerals designate corresponding parts throughout the several views.

FIG. 1 is an illustrative isometric view of a piezoelectric sensor in accordance with one embodiment of the present invention.

FIG. 2 is an exploded view of the piezoelectric sensor of FIG. 1.

FIG. 3 is an illustrative isometric view of an electronic device in accordance with one embodiment of the present invention.

### DETAILED DESCRIPTION OF THE EXEMPLARY EMBODIMENTS

The present invention will hereinafter be described in detail with reference to exemplary embodiments. To make the technical problems to be solved, technical solutions and beneficial effects of the present invention more apparent, the present invention is described in further detail together with the figures and the embodiments. It should be understood the specific embodiments described hereby is only to explain the disclosure, not intended to limit the disclosure.

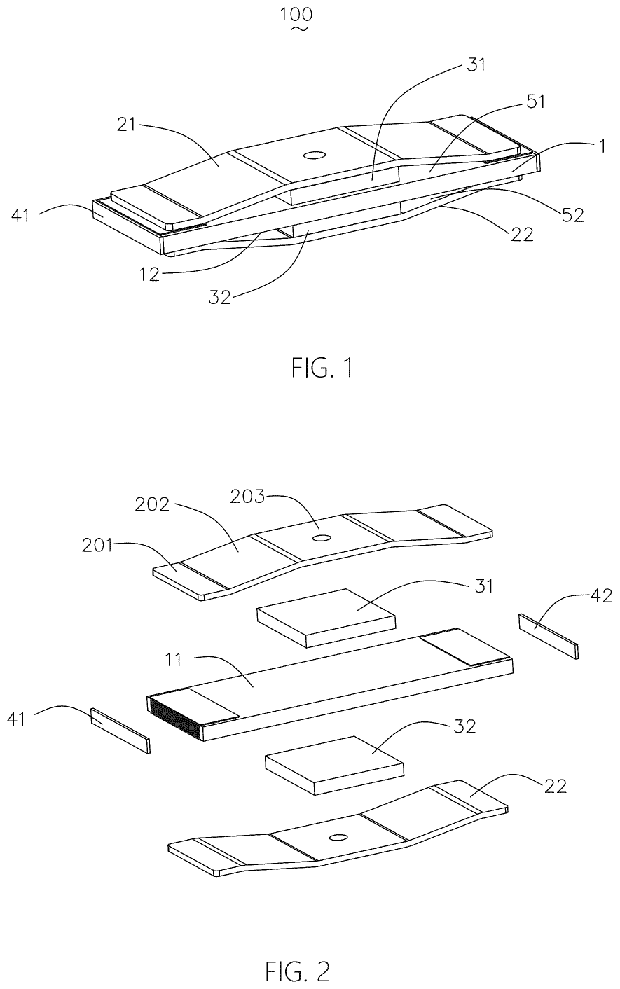

Referring to the FIGS. 1-2, the present invention provides one embodiment of a piezoelectric sensor 100. The piezoelectric sensor 100 includes a piezoelectric ceramic layer 1, a first metal shrapnel 21 and a second metal shrapnel 22 fixed with the piezoelectric ceramic layer 1, a first damping member 31 secured between the first metal shrapnel 21 and piezoelectric ceramic layer 1, a second damping member 32 secured between the second metal shrapnel 22 and piezoelectric ceramic layer 1, a first electrode 41 provided at one end of the piezoelectric ceramic layer 1, and a second electrode 42 provided at the other end of the piezoelectric ceramic layer 1.

The piezoelectric ceramic layer 1 includes a first surface 11 and a second surface 12 opposite to the first surface 11. A first cavity 51 is formed between the first metal shrapnel 21 and the first surface 11 of the piezoelectric ceramic layer 1. A second cavity 52 is formed between the second metal shrapnel 22 and the second surface 12 of the piezoelectric ceramic layer 1. The first damping member 31 locates in the first cavity 51 and fixed on the first surface 11 of the piezoelectric ceramic layer 1. The second damping member 32 locates in the second cavity 52 and fixed on the second surface 12 of the piezoelectric ceramic layer 1. The second damping member 32 is arranged symmetrically with the first damping member 31. Each of the first damping member 31 and the second damping member 32 is selected from one or more of foam, thermosetting glue, rubber, and silicone, and so on.

One side of the first damping member 31 is secured to the first surface 11 of the piezoelectric ceramic layer 1, and the other side of the first damping member 31 is abutted against the first metal shrapnel 21. One side of the second damping member 32 is secured to the second surface 12 of the piezoelectric ceramic layer 1, and the other side of the second damping member 32 is abutted against the second metal shrapnel 22. A length of the first damping member 31 accounts for 10% to 90% of a length of the piezoelectric ceramic layer 1, and a length of the second damping member 32 accounts for 10% to 90% of the length of the piezoelectric ceramic layer.

Each of the first metal shrapnel 21 and the second metal shrapnel 22 includes a fixation portion 201 fixed with the piezoelectric ceramic layer 1, an extension portion 202 extending obliquely from the fixation portion 201 in a direction away from the piezoelectric ceramic layer 1, and a horizontal portion 203 extending horizontally from the extension portion 202. The fixation portion 201 of the first metal shrapnel 21 and the fixation portion 201 of the second metal shrapnel 22 are fixed with the piezoelectric ceramic layer 1 by glue.

Both the first metal shrapnel 21 and the second metal shrapnel 22 have two fixation portions 201, two extension portions 202 and one horizontal portion 203, so that each of the first metal shrapnel 21 and the second metal shrapnel 22 has a trapezoidal shape.

The first electrode 41 is attached and fixed to one side surface of the piezoelectric ceramic layer 1 connecting the first surface 11 and the second surface 12, and the second electrode 42 is attached and fixed to the other side surface of the piezoelectric ceramic layer 1 connecting the first surface 11 and the second surface 12. The first electrode 41 and the second electrode 42 supply power to the piezoelectric ceramic layer 1.

The piezoelectric sensor 100 of the present invention provides the first damping member 31 and the second damping member 32, and the first damping member 31 and the second damping member 32 play a role in limiting and supporting the piezoelectric ceramic layer 1 disposed in the middle position, thereby reducing the internal stress of the piezoelectric ceramic layer and the glue. The piezoelectric sensor 100 of the present invention can improve its reliability. Through the test, the internal stress of the piezoelectric ceramic layer 1 was reduced to 70 MPa after improvement (with damping member added) from 133 MPa before (without damping member). And the internal stress of the glue was reduced to 18 Mpa after improvement (with damping member added) from 37 MPa before (without damping member). It can be seen that the performance of the piezoelectric sensor 100 has been significantly improved.

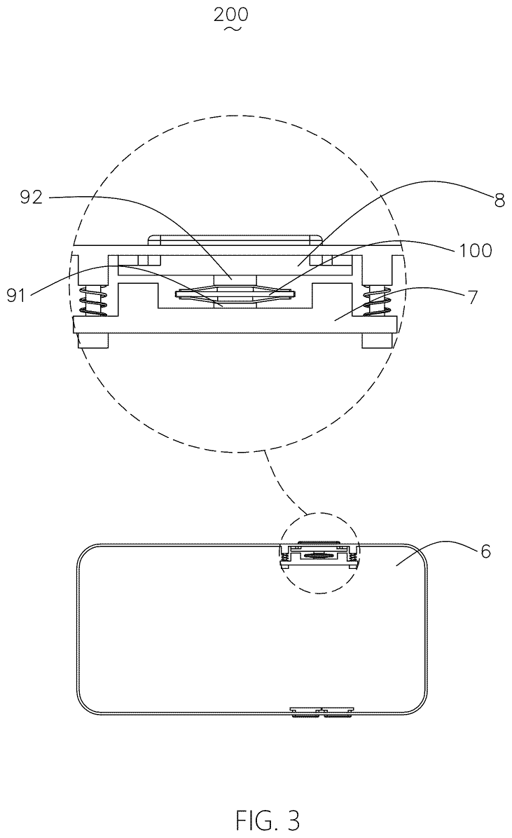

Referring to the FIGS. 1-3, the present invention provides one embodiment of an electronic device 200 in FIG. 3. The electronic device 200 includes a housing 6, a cover (not shown) covering with the housing 6, a frame 7 received in the housing 6, and a button 8 fixed to the housing 1. The electronic device 200 further includes the piezoelectric sensor 100 as described above. The piezoelectric sensor 100 locates between the frame 7 and the button 8. In detail, the electronic device 200 further includes a supporting member 91 connecting the piezoelectric sensor 100 to the frame 7 and a connecting member 92 connecting the piezoelectric sensor 100 and the button 8. The horizontal portion 203 of the first metal shrapnel 21 is fixedly attached to the connecting member 92 so that the piezoelectric sensor 100 can transmit a vibration to the button 8. The horizontal part 203 of the second metal shrapnel 22 is fixedly attached to the supporting member 91 so that the frame 7 can support the piezoelectric sensor 100.

Compared with related technologies, the present invention provides a piezoelectric sensor including a piezoelectric ceramic layer. The piezoelectric ceramic layer includes a first surface and a second surface opposite to the first surface. The piezoelectric sensor further includes a first metal shrapnel mounted on the first surface and a second metal shrapnel mounted on the second surface. A first cavity is formed between the first metal shrapnel and the piezoelectric ceramic layer and a second cavity is formed between the second metal shrapnel and the piezoelectric ceramic layer. The piezoelectric sensor further includes a first damping member located in the first cavity and fixed on the first surface and a second damping member located in the second cavity and fixed on the second surface. The second damping member is arranged symmetrically with the first damping member. The piezoelectric sensor of the present invention by setting first and second damping members, which play a role in limiting and supporting the piezoelectric ceramic layer disposed in the middle position, thereby reducing the internal stress of the piezoelectric ceramic layer and the glue. The piezoelectric sensor of the present invention improves its reliability.

Compared with related technologies, the present invention provides an electronic device including a housing, a frame received in the housing, a button fixed to the housing, and a piezoelectric sensor located between the frame and the button. The piezoelectric sensor includes a piezoelectric ceramic layer. The piezoelectric ceramic layer includes a first surface and a second surface opposite to the first surface. The piezoelectric sensor further includes a first metal shrapnel mounted on the first surface and a second metal shrapnel mounted on the second surface. A first cavity is formed between the first metal shrapnel and the piezoelectric ceramic layer and a second cavity is formed between the second metal shrapnel and the piezoelectric ceramic layer. The piezoelectric sensor further includes a first damping member located in the first cavity and fixed on the first surface and a second damping member located in the second cavity and fixed on the second surface. The second damping member is arranged symmetrically with the first damping member. The piezoelectric sensor of electronic device of the present invention by setting first and second damping members, which play a role in limiting and supporting the piezoelectric ceramic layer disposed in the middle position, thereby reducing the internal stress of the piezoelectric ceramic layer and the glue. The electronic device of the present invention improves its reliability.

It is to be understood, however, that even though numerous characteristics and advantages of the present exemplary embodiment have been set forth in the foregoing description, together with details of the structures and functions of the embodiment, the disclosure is illustrative only, and changes may be made in detail, especially in matters of shape, size, and arrangement of parts within the principles of the invention to the full extent indicated by the broad general meaning of the terms where the appended claims are expressed.

What is claimed is:

1. A piezoelectric sensor, comprising:
a piezoelectric ceramic layer, the piezoelectric ceramic layer comprising a first surface and a second surface opposite to the first surface;
a first metal shrapnel mounted on the first surface, a first cavity formed between the first metal shrapnel and the piezoelectric ceramic layer;
a second metal shrapnel mounted on the second surface, a second cavity formed between the second metal shrapnel and the piezoelectric ceramic layer;
a first damping member located in the first cavity and fixed on the first surface; and
a second damping member located in the second cavity and fixed on the second surface, the second damping member arranged symmetrically with the first damping member.

2. The piezoelectric sensor as described in claim 1, wherein one side of the first damping member is secured to the first surface of the piezoelectric ceramic layer, and the other side of the first damping member is abutted against the first metal shrapnel; one side of the second damping member is secured to the second surface of the piezoelectric ceramic layer, and the other side of the second damping member is abutted against the second metal shrapnel.

3. The piezoelectric sensor as described in claim 2, wherein each of the first damping member and the second damping member is selected from one or more of foam, thermosetting glue, rubber, and silicone.

4. The piezoelectric sensor as described in claim 1, wherein a length of the first damping member accounts for 10% to 90% of a length of the piezoelectric ceramic layer, and a length of the second damping member accounts for 10% to 90% of the length of the piezoelectric ceramic layer.

5. The piezoelectric sensor as described in claim 1, wherein each of the first metal shrapnel and the second metal shrapnel comprises a fixation portion fixed with the piezoelectric ceramic layer, an extension portion extending obliquely from the fixation portion in a direction away from the piezoelectric ceramic layer, and a horizontal portion extending horizontally from the extension portion.

6. The piezoelectric sensor as described in claim 5, wherein the fixation portion of the first metal shrapnel and the fixation portion of the second metal shrapnel are fixed with the piezoelectric ceramic layer by glue.

7. An electronic device, comprising:
a housing;
a frame received in the housing;
a button fixed to the housing; and
a piezoelectric sensor located between the frame and the button, the piezoelectric sensor comprising:
a piezoelectric ceramic layer, the piezoelectric ceramic layer comprising a first surface and a second surface opposite to the first surface;
a first metal shrapnel mounted on the first surface, a first cavity formed between the first metal shrapnel and the piezoelectric ceramic layer;
a second metal shrapnel mounted on the second surface, a second cavity formed between the second metal shrapnel and the piezoelectric ceramic layer;
a first damping member located in the first cavity and fixed on the first surface; and
a second damping member located in the second cavity and fixed on the second surface, the second damping member arranged symmetrically with the first damping member.

8. The electronic device as described in claim 7, wherein the electronic device further comprises a supporting member connecting the piezoelectric sensor to the frame and a connecting member connecting the piezoelectric sensor and the button.

9. The electronic device as described in claim 7, wherein one side of the first damping member is secured to the first surface of the piezoelectric ceramic layer, and the other side of the first damping member is abutted against the first metal shrapnel; one side of the second damping member is secured to the second surface of the piezoelectric ceramic layer, and the other side of the second damping member is abutted against the second metal shrapnel.

10. The electronic device as described in claim 9, wherein each of the first damping member and the second damping member is selected from one or more of foam, thermosetting glue, rubber, and silicone.

11. The electronic device as described in claim 7, wherein a length of the first damping member accounts for 10% to 90% of a length of the piezoelectric ceramic layer, and a length of the second damping member accounts for 10% to 90% of the length of the piezoelectric ceramic layer.

12. The electronic device as described in claim 7, wherein each of the first metal shrapnel and the second metal shrapnel comprises a fixation portion fixed with the piezoelectric ceramic layer, an extension portion extending obliquely from the fixation portion in a direction away from the piezoelectric ceramic layer, and a horizontal portion extending horizontally from the extension portion.

13. The electronic device as described in claim 12, wherein the fixation portion of the first metal shrapnel and the fixation portion of the second metal shrapnel are fixed with the piezoelectric ceramic layer by glue.
